(19) United States
(12) Patent Application Publication
(10) Pub. No.: US 2010/0032754 A1
(43) Pub. Date: Feb. 11, 2010

(54) Semiconductor device and method of manufacturing the semiconductor device

(75) Inventor: Hiroshi Kawaguchi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/461,161

(22) Filed: Aug. 3, 2009

(30) Foreign Application Priority Data
Aug. 11, 2008 (JP) 207358/2008

(51) Int. Cl. H01L 29/78; H01L 21/336

(52) U.S. Cl. 257/337; 438/275; 257/E29.256; 257/E21.417

(57) ABSTRACT

A semiconductor device includes: a high withstanding voltage transistor (128); a gate electrode (110) formed on a channel region (170); a first conductivity type source region (116a) formed on one side of the channel region (170) and a first conductivity type drain region (116b) formed on another side of the channel region (116a); and a drift region (172) which is provided between the source region (116a) and the drain region (116b) and has a super junction structure in which first conductivity type impurity diffusion regions and second conductivity type impurity diffusion regions are alternately arranged at regular intervals of a constant width in a gate width direction of the gate electrode (110). The gate electrode has a comb-shaped structure in plan view, the comb-shaped structure including comb teeth which cover the second conductivity type impurity diffusion regions of the drift region (172).

### BACKGROUND OF THE INVENTION

1. Field of the Invention

The present invention relates to a semiconductor device and to a method of manufacturing the semiconductor device.

2. Description of the Related Art

Conventionally, there has been known a lateral field effect transistor which has a super junction structure (see, U.S. Pat. No. 7,023,050, U.S. Pat. No. 7,202,526, U.S. Pat. No. 7,105,387 (referred to as Patent Documents 1 to 3), and S. Iwamoto, K. Takahashi, H. Kuribayashi, S. Wakimoto, K. Mochizuki, and H. Nakazawa, “Above 500 V class Super junction MOSFETs fabricated by deep trench etching and epitaxial growth”, Proceedings of the 17 International Symposium on Power Semiconductor Devices & IC's, May 23 to 26, 2005 (hereinafter, referred to as Non-patent Document 1)).

FIG. 17 is a plan view illustrating a structure of the lateral field effect transistor. In FIG. 17, a surface structure of a semiconductor substrate 22 of a semiconductor device 10 and a gate electrode 24 are illustrated. The semiconductor device 10 includes a p-type channel region 12, a p-type impurity diffusion region 14, an n-type source region 16a, an n-type drain region 16b, and a drift region 18 provided between the channel region 12 and the drain region 16b. The drift region 18 has a super junction structure in which n-type pillars 20a and p-type pillars 20b are alternately arranged at regular intervals in a gate width direction of the gate electrode 24.

The super junction structure as described above enables the n-type pillars 20a and the p-type pillars 20b to be completely depleted in a predetermined electric field, and hence the electric field of the transistor with the super junction structure is more mitigated compared with that of a transistor without the super junction structure. Accordingly, even when an impurity concentration of a substrate surface is set to be high, a high withstanding voltage characteristic is achieved.

The present inventor has recognized as follows. Conventionally, there has been a problem that manufacturing steps are complicated in forming the super junction structure of the drift region 18. That is, for example, a trench is formed in a substrate having one conductivity type and a pillar having an opposite conductivity type is formed by epitaxial growth as described in Non-patent Document 1.

In addition, when forming the drift region 18, it is necessary to take an alignment error with respect to the gate electrode 24 into consideration. Therefore, a margin needs to be added between the gate electrode 24 and the drift region 18 as indicated by an arrow of FIG. 17, which causes a problem that a device area becomes larger. Moreover, the alignment error may cause characteristic fluctuations in terms of withstanding voltage, resistance during the operation, and the like.

### SUMMARY

According to one aspect of the present invention, there is provided a semiconductor device comprising a field effect transistor, which includes: a substrate; a gate electrode formed on a channel region of the substrate; a first conductivity type source region formed on one side of the channel region and a first conductivity type drain region formed on another side of the channel region above a surface of the substrate; and a drift region which is provided between the channel region and the drain region and has a super junction structure in which first conductivity type impurity diffusion regions and second conductivity type impurity diffusion regions are alternately arranged at regular intervals of a constant width in a gate width direction of the gate electrode, wherein the gate electrode is formed in a comb-shaped structure in plan view, the comb-shaped structure including comb teeth which cover the second conductivity type impurity diffusion regions of the drift region.

According to another aspect of the present invention, there is provided a method of manufacturing a semiconductor device. The method comprises forming a field effect transistor, the forming the field effect transistor including: forming, on a channel region of a substrate, a comb-shaped gate electrode including comb teeth at least on one side of the channel region in a gate length direction, the substrate having a surface on which a second conductivity type region is formed; implanting first conductivity type impurity ions into the substrate with the gate electrode being used as a mask and forming first conductivity type impurity diffusion regions in regions between the comb teeth of the gate electrode, to thereby form a drift region having a super junction structure in which the first conductivity type impurity diffusion regions and second conductivity type impurity diffusion regions are alternately arranged at regular intervals of a constant width in a gate width direction of the gate electrode; and implanting the first conductivity type impurity ions into both sides of the channel region of the substrate, to thereby form a first conductivity type drain region on the one side of the channel region and a first conductivity type source region on another side of the channel region in the gate length direction.

According to the above-mentioned structure, the field effect transistor includes the comb-shaped gate electrode, and hence the drift region may be formed in a self-aligning manner with the gate electrode being used as a mask. Therefore, the distance between the gate electrode and the drift region may be defined by the shape of the gate electrode. Compared with a case where the drift region is formed independently of the gate electrode, there is no need to provide a margin, which is otherwise formed in consideration of an alignment error, whereby a device area may be prevented from being unnecessarily increased. Moreover, the alignment error is not caused, and hence characteristic fluctuations in withstanding voltage, resistance during the operation, and the like may be prevented.

It should be noted that an effective mode of the present invention includes an arbitrary combination of the above-mentioned components and replacement between a method and a device in terms of the expression of the present invention.

According to the present invention, there is obtained a semiconductor device including a lateral field effect transistor having high alignment accuracy with a simple procedure.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a perspective view illustrating a structure of a semiconductor device according to a first embodiment of the present invention;

FIG. 2 is a plan view illustrating a surface structure of a semiconductor substrate of the semiconductor device according to the first embodiment of the present invention;

FIGS. 3A and 3B are views each illustrating a manufacturing procedure of the semiconductor device according to the first embodiment of the present invention;

FIGS. 4A to 4C are views each illustrating the manufacturing procedure of the semiconductor device according to the first embodiment of the present invention;

FIGS. 5A to 5C are views each illustrating the manufacturing procedure of the semiconductor device according to the first embodiment of the present invention;

FIGS. 6A to 6C are views each illustrating the manufacturing procedure of the semiconductor device according to the first embodiment of the present invention;

FIGS. 7A and 7B are views each illustrating the manufacturing procedure of the semiconductor device according to the first embodiment of the present invention;

FIGS. 8A and 8B are views each illustrating the manufacturing procedure of the semiconductor device according to the first embodiment of the present invention;

FIGS. 9A and 9B are views each illustrating the manufacturing procedure of the semiconductor device according to the first embodiment of the present invention;

FIG. 10 is a plan view illustrating a semiconductor device according to a second embodiment of the present invention;

FIGS. 11A and 11B are step cross-sectional views each illustrating a manufacturing procedure of the semiconductor device according to the second embodiment of the present invention;

FIGS. 12A and 12B are step cross-sectional views each illustrating the manufacturing procedure of the semiconductor device according to the second embodiment of the present invention;

FIGS. 13A and 13B are step cross-sectional views each illustrating the manufacturing procedure of the semiconductor device according to the second embodiment of the present invention;

FIGS. 14A and 14B are step cross-sectional views each illustrating the manufacturing procedure of the semiconductor device according to the second embodiment of the present invention;

FIGS. 15A and 15B are step cross-sectional views each illustrating the manufacturing procedure of the semiconductor device according to the second embodiment of the present invention;

FIG. 16 is a plan view illustrating the semiconductor device according to the second embodiment of the present invention;

FIG. 17 is a plan view illustrating a structure of a semiconductor device, for describing problems of the related art; and

FIG. 18 is a plan view illustrating an example of a surface structure of a semiconductor substrate of a semiconductor device according to another embodiment of the present invention.

### DETAILED DESCRIPTION OF THE PREFERRED EMBODIMENTS

Hereinafter, embodiments of the present invention are described with reference to the accompanying drawings. It should be noted that the same components are denoted by the same reference symbols in the respective drawings, and descriptions thereof are appropriately omitted.

### First Embodiment

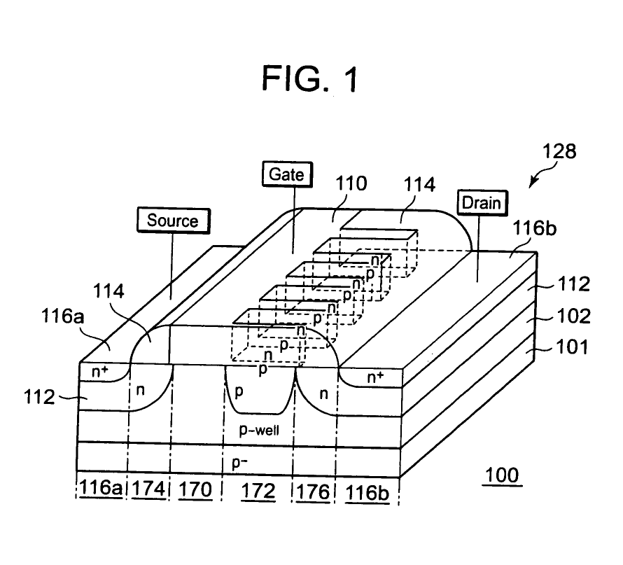

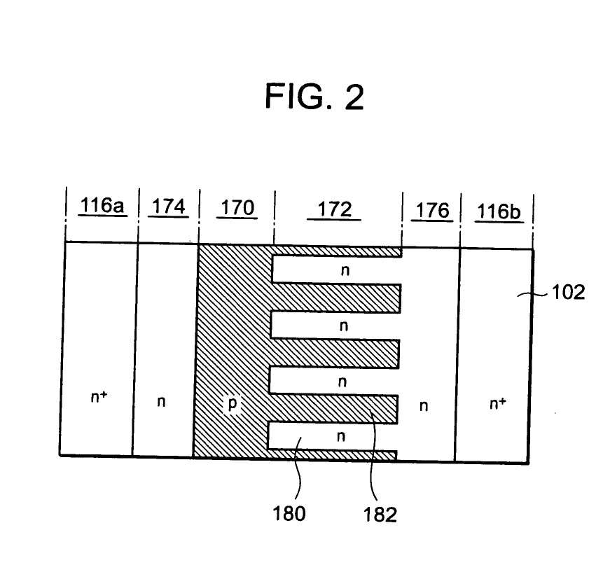

FIG. 1 is a perspective view illustrating a structure of a semiconductor device according to this embodiment. FIG. 2 is a plan view illustrating a surface structure of a semiconductor substrate of the semiconductor device.

In this embodiment, a semiconductor device 100 includes a high withstanding voltage transistor 128 that is a lateral field effect transistor. The semiconductor device 100 includes a semiconductor substrate (substrate) 101, a p-well 102 formed on the semiconductor substrate 101, a gate electrode 110 formed on a p-type (second conductivity type) channel region 170 inside the p-well 102, and a sidewall 114 formed on both sides of the gate electrode 110.

The semiconductor device 100 includes, on a surface of the semiconductor substrate 101, an n-type (first conductivity type) source region 116a formed on one side of the channel region 170, an n-type drain region 116b formed on another side of the channel region 170, a drift region 172 provided between the channel region 170 and the drain region 116b, an n-type extension region 174 provided between the channel region 170 and the source region 116a, and an n-type extension region 176 provided between the drift region 172 and the drain region 116b.

Here, the drift region 172 has a super junction structure in which n-type impurity diffusion regions (pillars) 180 and p-type impurity diffusion regions (pillars) 182 are alternately arranged at regular intervals of a constant width in a gate width direction of the gate electrode 110. As described later, the n-type impurity diffusion regions 180 are formed by implanting an n-type impurity into a region (p-type impurity diffusion region 106) into which a p-type impurity is introduced in advance. In this case, a concentration of the implanted n-type impurity is higher than that of the p-type impurity of the p-type impurity diffusion region 106. Meanwhile, in the super junction structure as in the case of the drift region 172, it is desirable to set space charges to be equal between the p-type impurity diffusion regions and the n-type impurity diffusion regions. Widths and intervals of comb teeth of the gate electrode 110 are determined by the above-mentioned matters. When the width of the comb tooth of the gate electrode 110 is set to be larger than the interval between the comb teeth thereof, balance of the space charge may be satisfactorily achieved. In this embodiment, the gate electrode 110 is formed in a comb-shaped structure in plan view, which includes the comb teeth that cover the p-type impurity diffusion regions 182 of the drift region 172. In this embodiment, the gate electrode 110 has a shape that overlaps the channel region 170 and the p-type impurity diffusion regions 182 of the drift region 172. In this embodiment, the n-type impurity diffusion regions 180 of the drift region 172 are formed in a self-aligning manner with the comb teeth of the gate electrode 110 being used as a mask.

The sidewall 114 fills regions between the comb teeth of the gate electrode 110 on the p-type impurity diffusion regions 182 of the drift region 172. In this embodiment, the source region 116a and the drain region 116b are formed in a self-aligning manner with the sidewall 114 being used as a mask. Thus, an interval between the channel region 170 and the source region 116a and an interval between the drift region 172 and the drain region 116b are defined by the width of the sidewall 114.

It should be noted that, in this embodiment, a description is made of an n-type field effect transistor (n-FET) as an example, in which the first conductivity type is an n-type and the second conductivity type is a p-type. Alternatively, a p-type field effect transistor (p-FET) in which the first conductivity type is a p-type and the second conductivity type is an n-type may be also formed by the same structure.

Further, this embodiment may have a structure in which the high withstanding voltage transistor 128 may have a withstanding voltage of, for example, approximately 10 to 20 V.

Next, a manufacturing procedure of the semiconductor device 100 according to this embodiment is described.

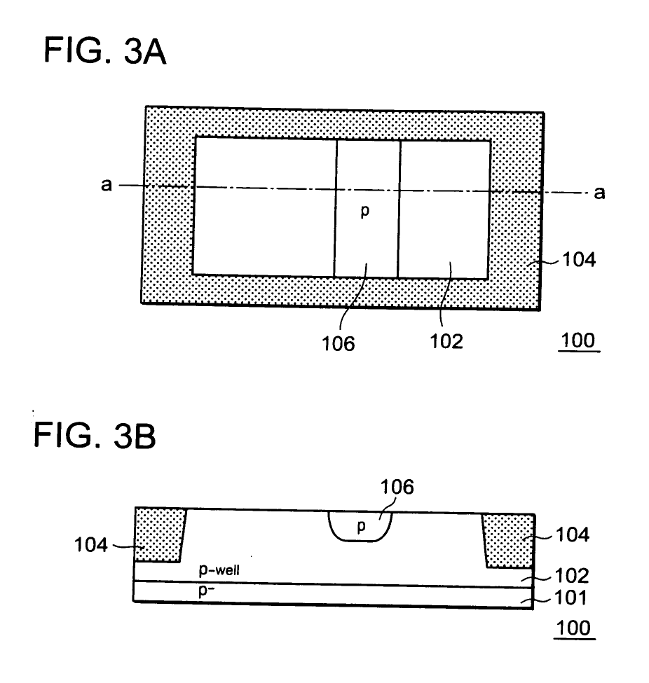

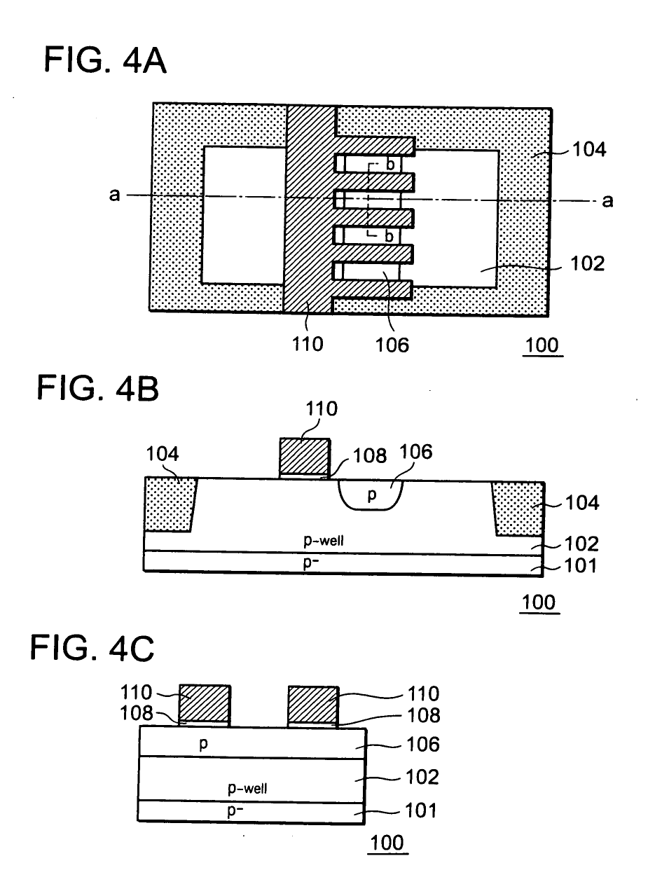

FIGS. 3A to 9B are views each illustrating the manufacturing procedure of the semiconductor device 100 according to this embodiment. FIGS. 3A, 4A, 5A, 6A, 7A, 8A, and 9A are plan views each illustrating a structure of the semiconductor device 100. FIGS. 3B, 4B, 5B, 6B, 7B, 8B, and 9B are cross-sectional views taken along the lines a-a of FIGS. 3A to 9A, respectively. FIGS. 4C, 5C, and 6C are cross-sectional views taken along the lines b-b of FIGS. 4A to 6A, respectively.

First, a device isolation insulating film 104 is formed on a surface of the semiconductor substrate 101. Subsequently, the p-well 102 is formed in a predetermined region on the surface of the semiconductor substrate 101. Then, the p-type impurity diffusion region 106 is formed by implanting p-type impurity ions (for example, under conditions of 15 keV and 6E12 cm-2) into a region that is to serve as the drift region 172, inside the p-well 102 on the semiconductor substrate 101 (FIGS. 3A and 3B)

After that, an insulating film for forming a gate insulating film 108 and a conductive film for forming the gate electrode 110 are laminated on an entire surface over the semiconductor substrate 101 in the stated order. In this embodiment, the gate insulating film 108 may be formed of, for example, a silicon oxide film, a high dielectric film, or a laminated film including the silicon oxide film and the high dielectric film. In this embodiment, the conductive film for forming the gate electrode 110 may be formed of, for example, polycrystalline silicon. Subsequently, the conductive film and the insulating film are patterned into a predetermined shape. As a result, the gate insulating film 108 and the gate electrode 110 are formed above the semiconductor substrate 101 (FIGS. 4A, 4B, and 4C).

In this embodiment, the gate electrode 110 is formed in a comb shape in plan view, and the comb teeth of the comb shape are arranged in the region that is to serve as the drift region 172. The comb teeth of the gate electrode 110 are formed so as to be opened at portions of the region that is to serve as the drift region 172 at which the n-type impurity diffusion regions 180 are formed, and to cover portions at which the p-type impurity diffusion regions 182 are formed. The gate insulating film 108 is patterned together with the gate electrode 110 to have the same shape as that of the gate electrode 110 in plan view.

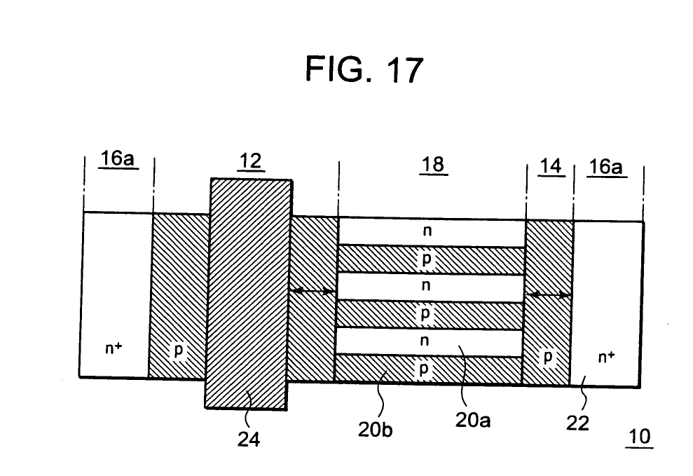

With this structure, a distance between the gate electrode 110 and the drift region 172 may be defined by the shape of the gate electrode 110. A margin indicated by an arrow of FIG. 17, which is formed in consideration of an alignment error as in a case of using a photo resist, does not need to be provided between the gate electrode 24 and the drift region 18, thereby preventing a device area from being unnecessarily increased.

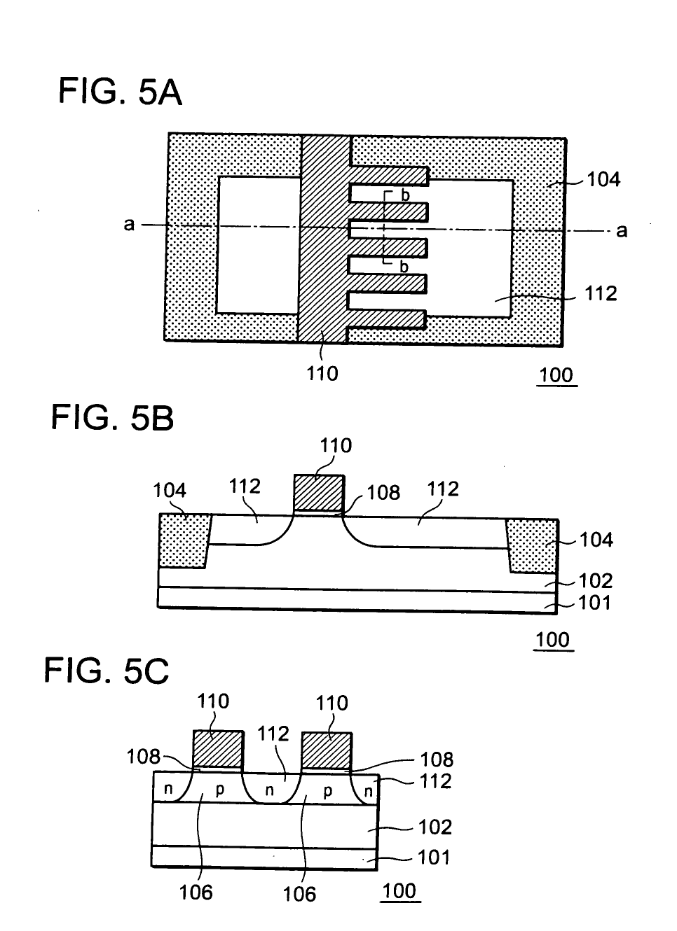

Next, n-type impurity diffusion regions 112 are formed by implanting n-type impurity ions (for example, under conditions of 10 keV and 1E13 cm-2) into the semiconductor substrate 101 with the gate electrode 110 being used as a mask (FIGS. 5A, 5B, and 5C). In this case, the concentration of the implanted n-type impurity ions may exceed the concentration of the p-type impurity ions in the p-type impurity diffusion region 106. In this embodiment, the gate electrode 110 is formed in the comb shape in plan view, and hence the n-type impurity ions are implanted into the regions between the comb teeth of the gate electrode 110 as illustrated in FIG. 5C. As a result, the super junction structure as illustrated in FIG. 2 is formed.

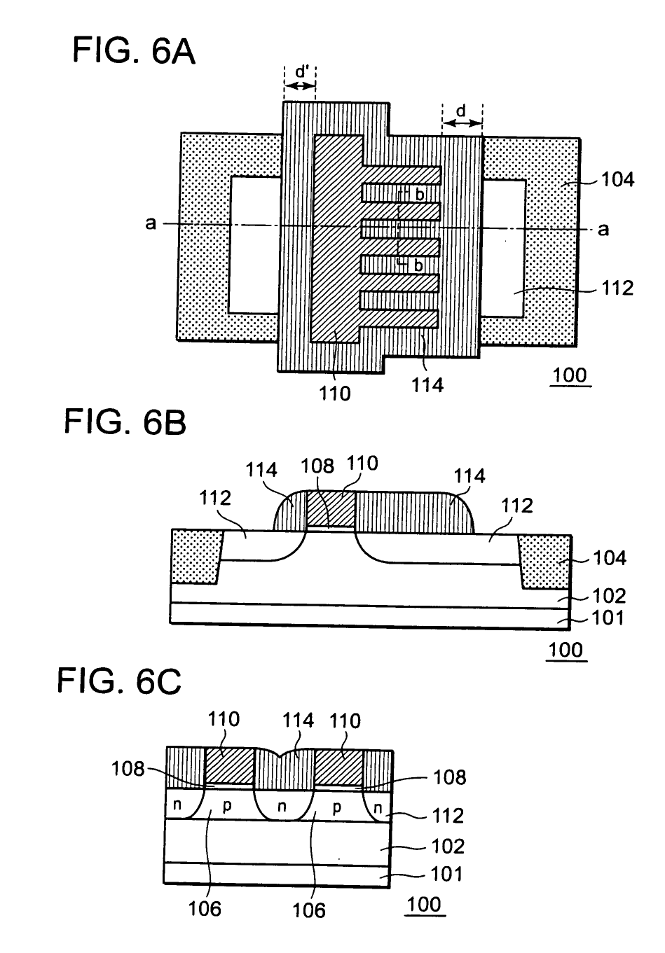

Next, an insulating film is formed on an entire surface over the semiconductor substrate 101. Here, the insulating film may be formed by, for example, depositing a silicon oxide (SiO₂) film by chemical vapor deposition (CVD) or by laminating the silicon oxide film deposited by CVD and a silicon nitride (Si₃N₄) film deposited by CVD. The film thickness of the deposited insulating film is set to be at least half the interval between the comb teeth of the gate electrode 110. In this way, spaces between the comb teeth of the gate electrode 110 may be filled with the insulating film. After that, an etch back is performed by anisotropic etching to expose the gate electrode 110 and portions of the semiconductor substrate 101 at which the source region 116a and the drain region 116b are formed, and to form the sidewall 114 on both sides of the gate electrode 110 (FIGS. 6A, 6B, and 6C). In this case, the spaces between the comb teeth of the gate electrode 110 are filled with the insulating film, and thus the insulating film remains even after the anisotropic etching is performed. Therefore, as in a case where the gate electrode 110 is formed over the entire surface to tips of the comb teeth thereof, the sidewall 114 may be formed such that a distance d is equivalent to a distance d′. The distance d indicates a distance from the tips of the comb teeth of the gate electrode 110 to one end of the sidewall 114 on a side of the drain region 116b to be formed. The distance d′ indicates a distance from an end of the gate electrode 110 to another end of the sidewall 114 on a side of the source region 116a to be formed.

With this structure, a distance between the gate electrode 110 and the drain region 116b may be defined by the sidewall 114. A margin as indicated by an arrow of FIG. 17, which is formed in consideration of an alignment error as in a case of using a photo resist, does not need to be provided between the gate electrode 24 and the drain region 16b, thereby preventing a device area from being unnecessarily increased.

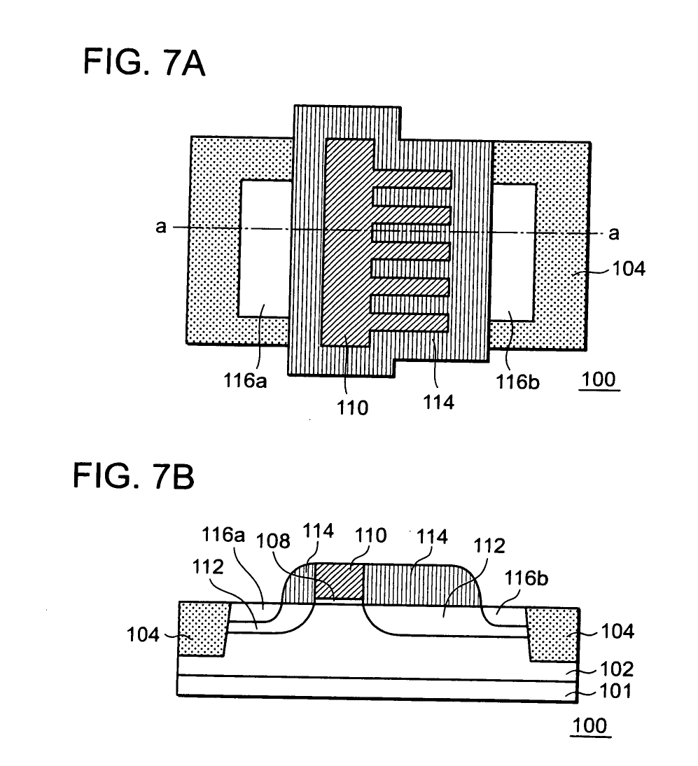

Next, the source region 116a and the drain region 116b are formed by implanting n-type impurity ions (for example, under conditions of 10 keV and 3E15 cm-2) into the semiconductor substrate 101 with the sidewall 114 being used as a mask (FIGS. 7A and 7B). In the case where the gate electrode 110 is formed of polycrystalline silicon, the n-type impurity ions are implanted also into the gate electrode 110. Then, the implanted ions are electrically activated inside the semiconductor substrate 101 through rapid thermal annealing (RTA) or the like, for example, in which heat treatment of 1,000° C. is performed for 30 seconds.

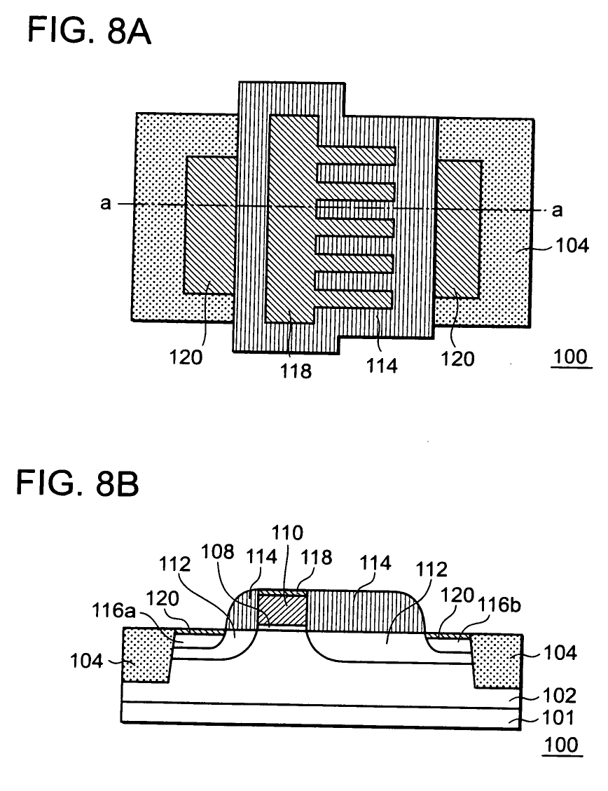

Subsequently, a metal layer such as an Ni or Co layer is formed on an entire surface over the semiconductor substrate 101, whereby the surfaces of the source region 116a and the drain region 116b are selectively silicided (salicided: self-aligned silicidation), the surfaces thereof being exposed above the semiconductor substrate 101. As a result, silicide layers 120 are formed on the surfaces of the source region 116a and the drain region 116b. At the same time, silicide layers 118 are formed on the surface of the gate electrodes 110 (FIGS. 8A and 8B).

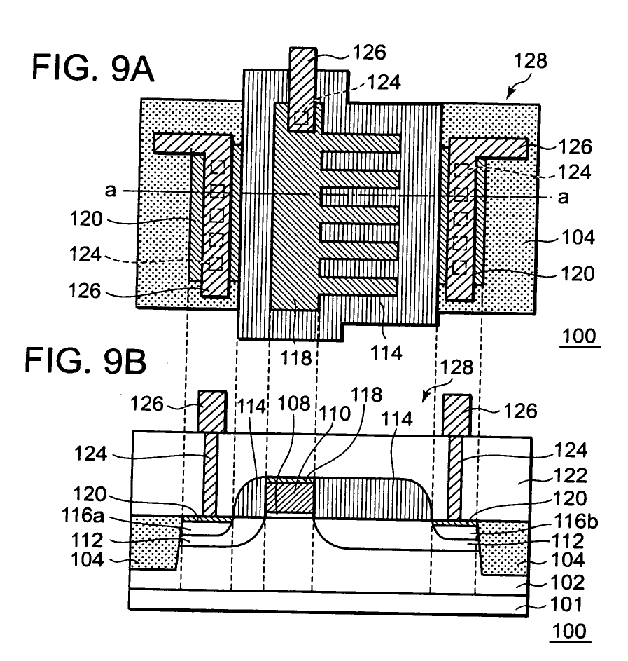

After that, an interlayer insulating film 122 is formed on an entire surface over the semiconductor substrate 101. Contact holes are formed in the interlayer insulating film 122 in order to expose the silicide layers 120 formed on the source region 116a and the drain region 116b, and the silicide layer 118 formed on the gate electrode 110. Subsequently, the contact holes are filled with a conductive material, to thereby form contacts 124. Further, an interlayer insulating film (not shown) is formed on the interlayer insulating film 122, and wiring grooves are formed in the formed interlayer insulating film. Then, the wiring grooves are filled with a conductive material, to thereby form wires 126. Through the above-mentioned procedure, the semiconductor device 100 is completed (FIGS. 9A and 9B).

According to the semiconductor device 100 of this embodiment, the high withstanding voltage transistor 128 includes the comb-shaped gate electrode 110, and hence the drift region 172 may be formed in a self-aligning manner with the gate electrode 110 being used as a mask. Therefore, the distance between the gate electrode 110 and the drift region 172 may be defined by the shape of the gate electrode 110. The margin formed in consideration of the alignment error as in the case of using a photo resist does not need to be provided, whereby the device area may be prevented from being unnecessarily increased.

Further, the gate electrode 110 has the comb shape, and hence the sidewall 114 may fill the regions between the comb teeth of the gate electrode 110, and the sidewall 114 having a predetermined width may be formed on both sides of the gate electrode 110. With this structure, the distance between the gate electrode 110 and the drain region 116b may be defined by the width of the sidewall 114. The margin formed in consideration of the alignment error as in the case of using a photo resist does not need to be provide, whereby the device area may be prevented from being unnecessarily increased.

It is assumed, for example, a case where the structure as in this embodiment is not employed and the drift region 172 is patterned using a photo resist or the like. In this case, in consideration of the alignment error, a resist film for forming the drift region 172 needs to be formed while a margin is provided with respect to the gate electrode 110. As a result, the distance between the gate electrode 110 and the drift region 172 is unnecessarily increased, whereby the device area becomes larger. According to the semiconductor device 100 of this embodiment, such a problem may be avoided. Moreover, the alignment error is not caused, and hence characteristic fluctuations in withstanding voltage, resistance during the operation, and the like may be prevented.

### Second Embodiment

A semiconductor device 100 according to this embodiment further includes, in addition to the high withstanding voltage transistor 128 described in the first embodiment, a low withstanding voltage transistor formed therein. Hereinafter, a procedure of simultaneously forming the high withstanding voltage transistor 128 and the low withstanding voltage transistor is described.

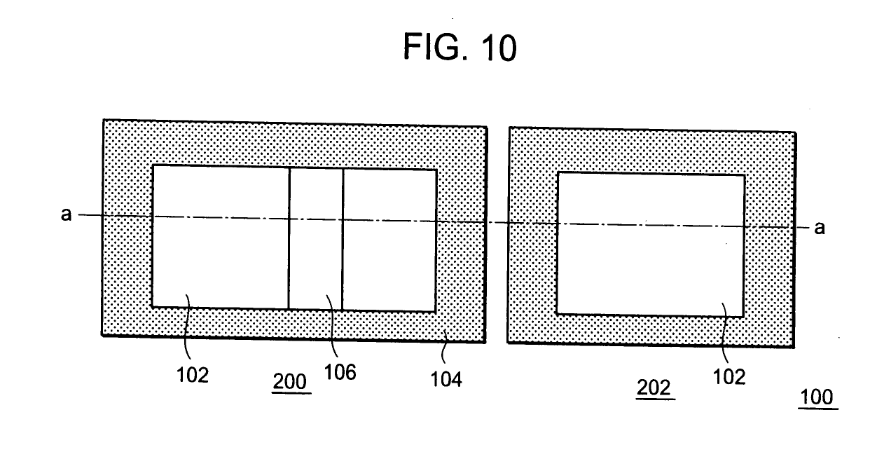

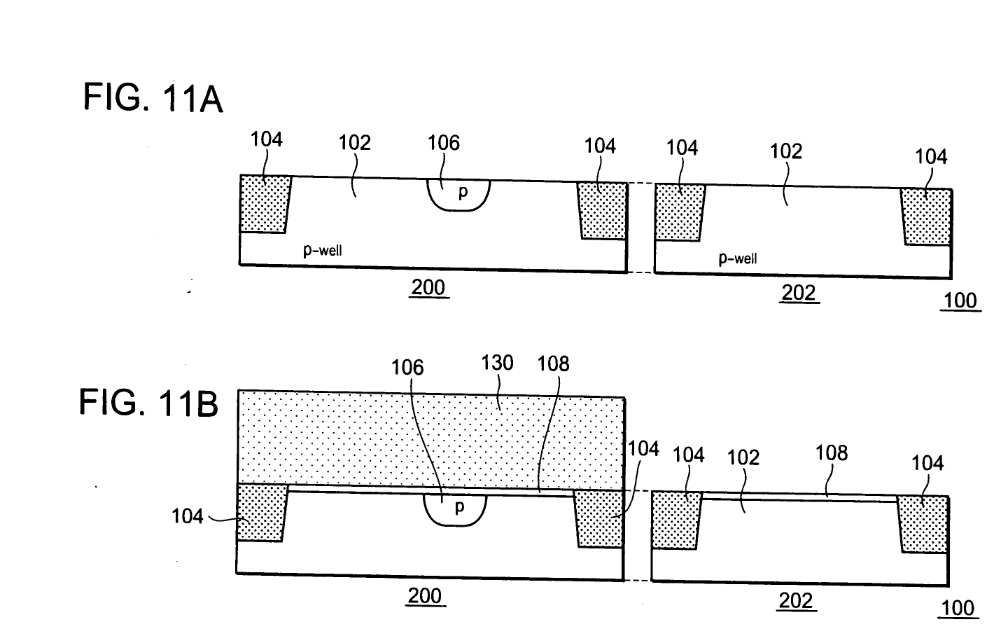

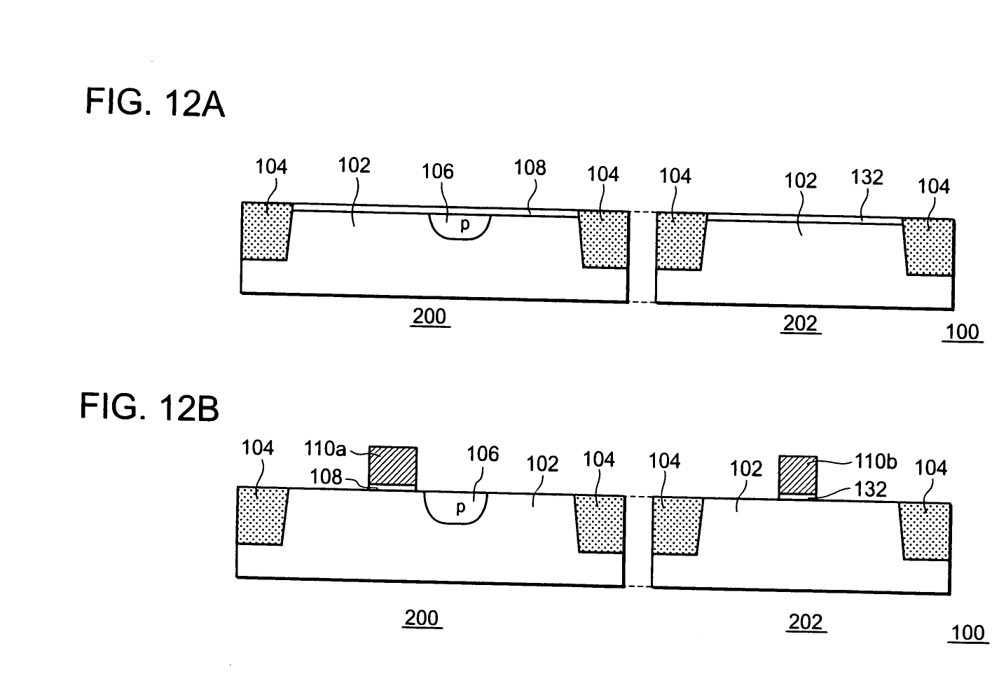

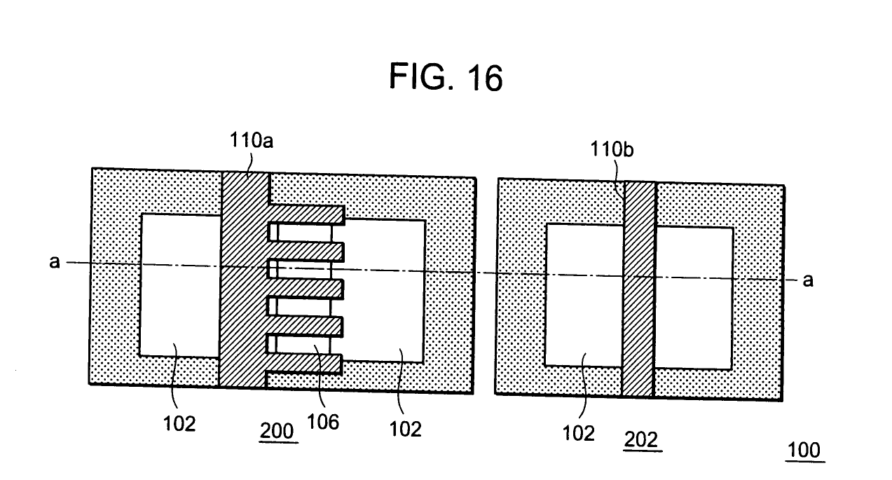

FIGS. 10 and 16 are plan views each illustrating the semiconductor device 100 according to this embodiment. FIGS. 11A to 15B are views each illustrating a manufacturing procedure of the semiconductor device 100 according to this embodiment. FIGS. 11A to 12A each correspond to a cross-sectional view taken along the line a-a of FIG. 10. FIGS. 12B to 15B each correspond to a cross-sectional view taken along the line a-a of FIG. 16.

The semiconductor device 100 is provided with a high withstanding voltage region 200 in which the high withstanding voltage transistor 128 is formed and a low withstanding voltage region 202 in which a low withstanding voltage transistor 142 is formed.

First, the device isolation insulating film 104 is formed on the surface of the semiconductor substrate (not shown). Subsequently, also in this embodiment, the p-well 102 is formed in a predetermined region on the surface of the semiconductor substrate. Similarly to the first embodiment, in this embodiment, the p-well 102 is formed on the surface of the semiconductor substrate 101, but the semiconductor substrate 101 is omitted from the drawings. Then, the p-type impurity diffusion region 106 is formed by implanting the p-type impurity ions (for example, under conditions of 15 keV and 6E12 cm-2) into the region that is to serve as the drift region 172, inside the p-well 102 on the semiconductor substrate of the high withstanding voltage region 200 (FIGS. 10 and 11A).

After that, the gate insulating film 108 is formed on an entire surface of the p-well 102 above the semiconductor substrate. Here, the gate insulating film 108 may be formed of, for example, a silicon oxide film obtained by oxidizing the surface of the p-well 102. Subsequently, a resist film 130 that selectively covers the high withstanding voltage region 200 and is opened in the low withstanding voltage region 202 is formed (FIG. 11B). Then, the gate insulating film 108 that is exposed in the low withstanding voltage region 202 is removed by etching with, for example, hydrogen fluoride (HF). Subsequently, agate insulating film 132 having a film thickness smaller than that of the gate insulating film 108 is formed in the low withstanding voltage region 202 (FIG. 12A). The gate insulating film 132 may be formed of, for example, a silicon oxide film obtained by oxidizing the surface of the p-well 102.

After that, a conductive film for forming the gate electrodes 110a and 110b is formed on an entire surface over the p-well 102. Subsequently, the conductive film and the gate insulating films 108 and 132 are patterned into a predetermined shape. As a result, the gate electrode 110a and the gate electrode 110b are formed in the high withstanding voltage region 200 and the low withstanding voltage region 202 above the p-well 102, respectively (FIGS. 16 and 12B). Here, the gate electrode 110a has the same structure as that of the gate electrode 110 described in the first embodiment. Further, the gate insulating film 108 is patterned together with the gate electrode 110a to have the same shape as that of the gate electrode 110a. Similarly, the gate insulating film 132 is patterned together with the gate electrode 110b to have the same shape as that of the gate electrode 110b.

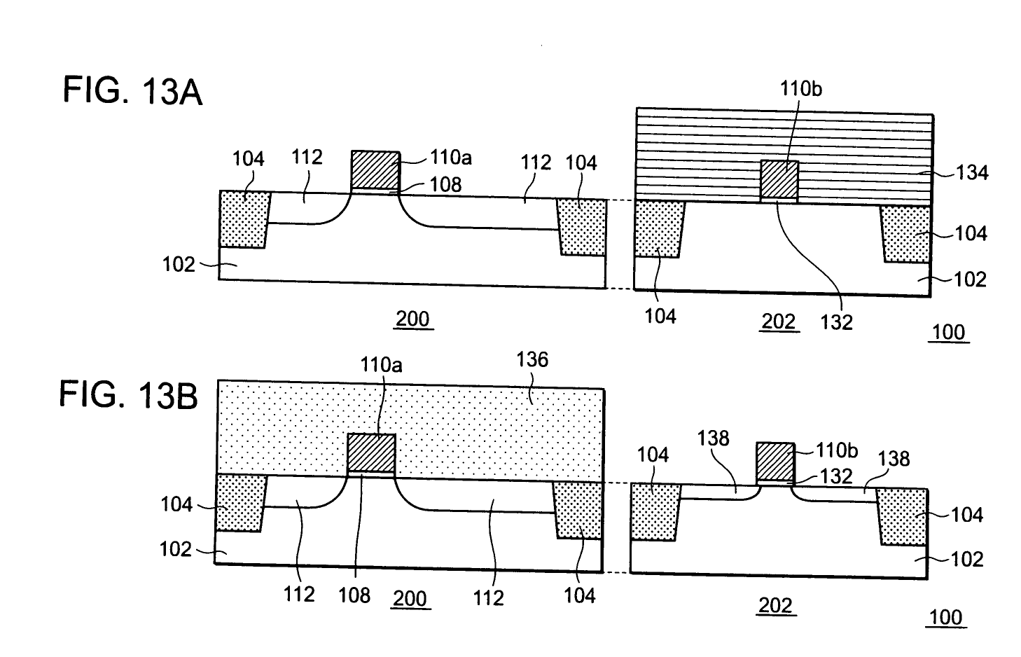

Then, a resist film 134 that selectively covers the low withstanding voltage region 202 and is opened in the high withstanding voltage region 200 is formed. Subsequently, the n-type impurity ions are implanted (for example, under conditions of 10 keV and 1E13 cm-2) into the p-well 102 with the gate electrode 110a being used as a mask, to thereby form an n-type impurity diffusion regions 112 in the high withstanding voltage region 200 (FIG. 13A). Here, the concentration of the implanted n-type impurity ions may be set to the same value as in the first embodiment.

After that, a resist film 136 that selectively covers the high withstanding voltage region 200 and is opened in the low withstanding voltage region 202 is formed. Subsequently, the n-type impurity ions are implanted (for example, under conditions of 20 keV and 1E14 cm-2) into the p-well 102 with the gate electrode 110b being used as a mask, to thereby form an n-type extension regions 138 in the high withstanding voltage region 200 (FIG. 13B).

Next, an insulating film is formed on an entire surface over the p-well 102. Here, the insulating film may be formed by, for example, depositing a silicon oxide (SiO₂) film by chemical vapor deposition (CVD) or by laminating the silicon oxide film deposited by CVD and a silicon nitride (Si₃N₄) film deposited by CVD. The film thickness of the deposited insulating film is set to be at least half the interval between comb teeth of the gate electrode 110a. In this way, spaces between the comb teeth of the gate electrode 110a may be filled with the insulating film.

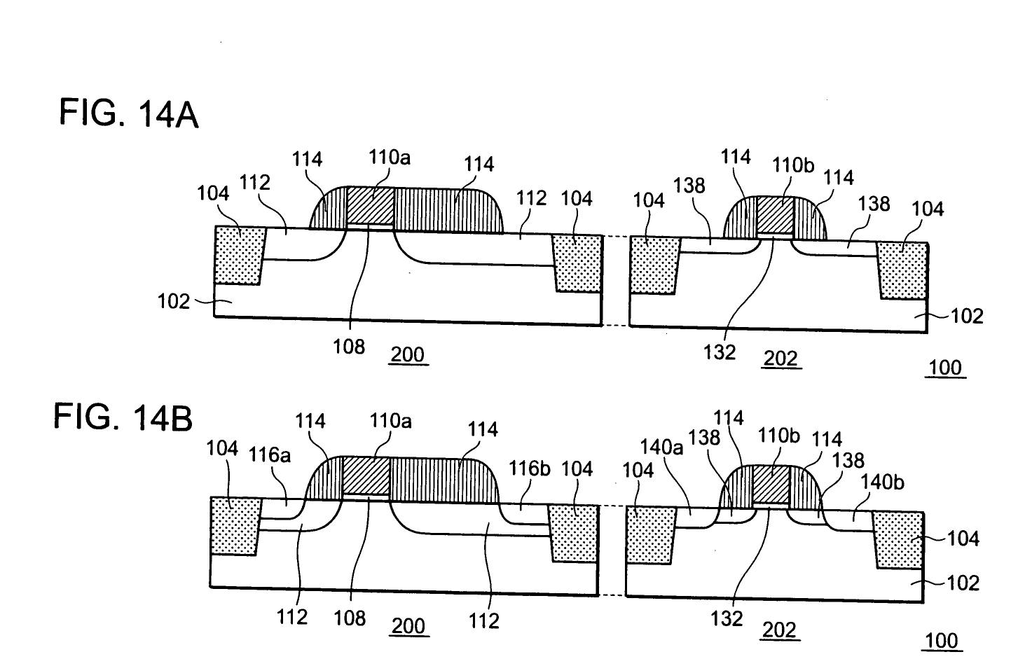

After that, anisotropic etching is performed to expose the gate electrodes 110a and 10b and portions of the semiconductor substrate at which the source region 116a and the drain region 116b are formed in the high withstanding voltage region 200 and at which a source region 140a and a drain region 140b are formed in the low withstanding voltage region 202. Further, the sidewalls 114 are formed on both sides of the gate electrode 110a and on both sides of the gate electrode 110b (FIG. 14A).

Next, then-type impurity ions are implanted (for example, under conditions of 10 keV and 3E15 cm-2) into the semiconductor substrate with the sidewalls 114 being used as a mask, to thereby form the source region 116a and the drain region 116b in the high withstanding voltage region 200 and the source region 140a and the drain region 140b in the low withstanding voltage region 202, respectively (FIG. 14B). Then, the implanted ions are electrically activated inside the semiconductor substrate through rapid thermal annealing (RTA) or the like, for example, in which heat treatment of 1,000° C. is performed for 30 seconds.

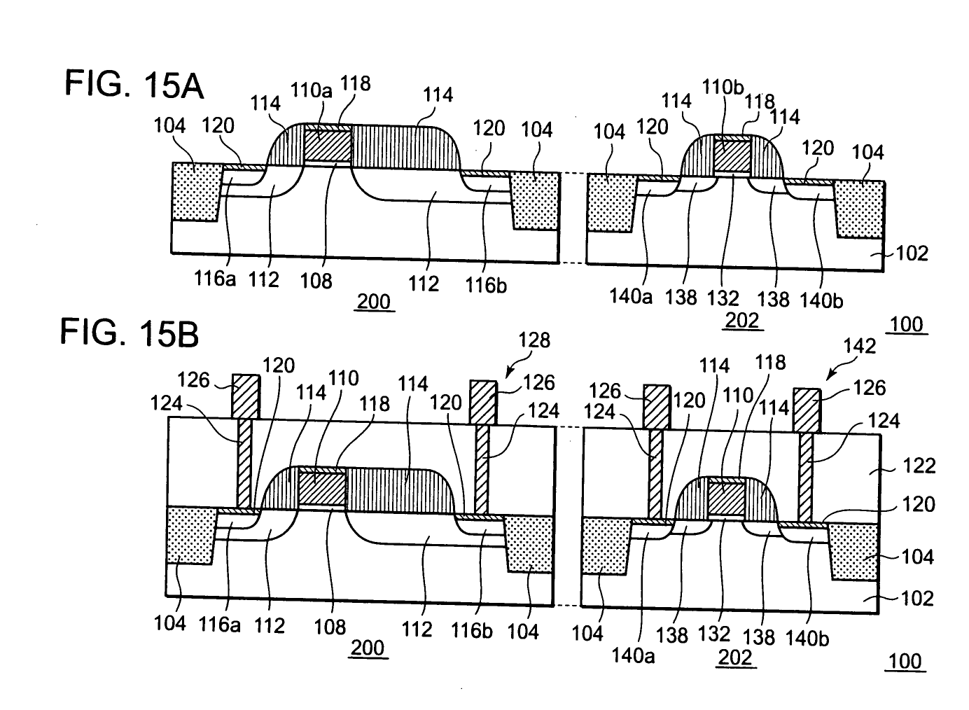

Subsequently, a metal layer such as an Ni or Co layer is formed on an entire surface over the semiconductor substrate, whereby the surfaces of the source region 116a, the drain region 116b, the source region 140a, the drain region 140b, and the gate electrodes 110a and 110b are selectively silicided (salicided: self-aligned silicidation), the surfaces thereof being exposed above the semiconductor substrate. As a result, silicide layers 120 are formed on the surfaces of the source region 116a, the drain region 116b, the source region 140a, and the drain region 140b. At the same time, silicide layers 118 are formed on the surfaces of the gate electrodes 110a and 110b (FIG. 15A).

After that, an interlayer insulating film 122 is formed on an entire surface over the semiconductor substrate. Contact holes are formed in the interlayer insulating film 122 in order to expose the silicide layers 120 formed on the source region 116a, the drain region 116b, the source region 140a, and the drain region 140b and the silicide layers 118 formed on the gate electrodes 110a and 110b. Subsequently, the contact holes are filled with a conductive material, to thereby form contacts 124. Further, an interlayer insulating film (not shown) is formed on the interlayer insulating film 122, and wiring grooves are formed in the formed interlayer insulating film. Then, the wiring grooves are filled with a conductive material, to thereby form wires 126. Through the above-mentioned procedure, the semiconductor device 100 is completed (FIG. 15B).

Also in this embodiment, the same effect as that of the first embodiment may be obtained. The low withstanding voltage transistor 142 and the high withstanding voltage transistor 128 may be formed in the same step with a simple procedure.

Hereinabove, the embodiments of the present invention, which are described with reference to the accompanying drawings, are taken as mere examples of the present invention. Therefore, the present invention may adopt various structures in addition to those of the embodiments.

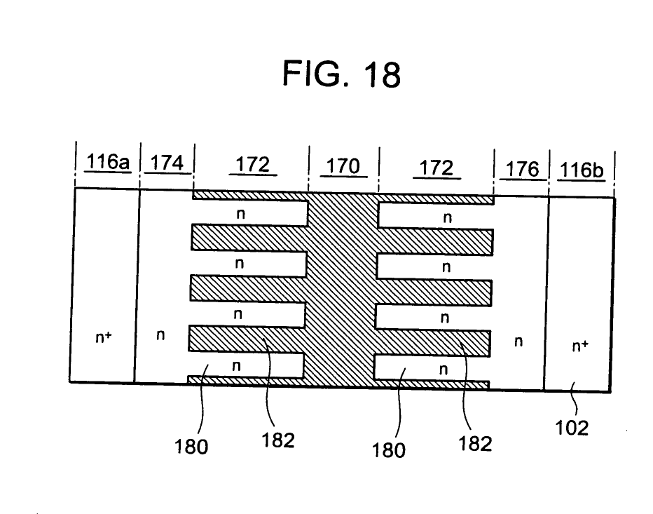

In the embodiments described above, there is exemplified the case where the drift region 172 is formed between the channel region 170 and the drain region 116b of the high withstanding voltage transistor 128. However, there may be adopted a structure in which the drift region 172 is also provided between the channel region 170 and the source region 116a. The high withstanding voltage transistor 128 having the above-mentioned structure may be formed in the following manner. That is, the comb teeth of the gate electrode 110 are provided also on the source region 116a side, and the n-type impurity diffusion region 112 is formed using the gate electrode 110 as a mask. FIG. 18 is a plan view illustrating a surface structure of the p-well 102 on the semiconductor substrate of the semiconductor device 110 having the above-mentioned structure. With this structure, even in a case where a source and a drain are switched in functions thereof to be used, a high withstanding voltage characteristic of the high withstanding voltage transistor 128 may be achieved.

In the embodiments described above, there is exemplified the case where the p-type impurity diffusion region 106 is selectively provided only in the region that is to serve as the drift region 172, but the p-well 102 may serve as the p-type impurity diffusion region 106. Specifically, it is possible to set the p-type impurity diffusion regions 182 of the drift region 172 and the channel region 170 so as to have the same concentration profile.

It is apparent that the present invention is not limited to the above embodiments, but may be modified and changed without departing from the scope and sprit of the invention.

What is claimed is:

1. A semiconductor device comprising a field effect transistor, the field effect transistor including:
a substrate;
a gate electrode formed on a channel region of the substrate;
a first conductivity type source region formed on one side of the channel region and a first conductivity type drain region formed on another side of the channel region above a surface of the substrate; and
a drift region which is provided between the channel region and the drain region and has a super junction structure in which first conductivity type impurity diffusion regions and second conductivity type impurity diffusion regions are alternately arranged at regular intervals of a constant width in a gate width direction of the gate electrode,
wherein the gate electrode is formed in a comb-shaped structure in plan view, the comb-shaped structure including comb teeth which cover the second conductivity type impurity diffusion regions of the drift region.

2. A semiconductor device according to claim 1, wherein the first conductivity type impurity diffusion regions in the drift region are formed in a self-aligning manner with the comb teeth of the gate electrode being used as a mask.

3. A semiconductor device according to claim 1, further comprising a sidewall which is formed on both sides of the gate electrode in a gate length direction above the substrate and fills regions between the comb teeth of the gate electrode on the first conductivity type impurity diffusion regions in the drift region.

4. A semiconductor device according to claim 3, wherein the source region and the drain region are formed in a self-aligning manner with the sidewall being used as a mask.

5. A semiconductor device according to claim 1, further comprising another drift region provided between the channel region and the source region,
wherein the comb teeth of the gate electrode are provided on the another drift region provided between the channel region and the source region.

6. A semiconductor device according to claim 1, further comprising, on the substrate, a second field effect transistor which is provided in the same layer as the field effect transistor and has a withstanding voltage lower than a withstanding voltage of the field effect transistor,
wherein the second field effect transistor includes:
a second gate electrode formed on a second channel region of the substrate;
a first conductivity type second source region formed on one side of the second channel region and a first conductivity type second drain region formed on another side of the second channel region, above the surface of the substrate; and
first conductivity type extension regions which are each provided between the second channel region and the second source region and between the second channel region and the second drain region.

7. A method of manufacturing a semiconductor device, comprising forming a field effect transistor, the forming the field effect transistor including:
forming, on a channel region of a substrate, a comb-shaped gate electrode including comb teeth at least on one side of the channel region in a gate length direction, the substrate having a surface on which a second conductivity type region is formed;
implanting first conductivity type impurity ions into the substrate with the gate electrode being used as a mask and forming first conductivity type impurity diffusion regions in regions between the comb teeth of the gate electrode, to thereby form a drift region having a super junction structure in which the first conductivity type impurity diffusion regions and second conductivity type impurity diffusion regions are alternately arranged at regular intervals of a constant width in a gate width direction of the gate electrode; and
implanting the first conductivity type impurity ions into both sides of the channel region of the substrate, to thereby form a first conductivity type drain region on the one side of the channel region and a first conductivity type source region on another side of the channel region in the gate length direction.

8. A method of manufacturing a semiconductor device according to claim 7, wherein the forming the first conductivity type source region and the first conductivity type drain region further includes:
forming an insulating film on an entire surface over the substrate, and embedding the gate electrode in the insulating film;
etching back the insulating film by dry etching, to thereby form a sidewall on both sides of the gate electrode in a gate length direction, the sidewall filling regions between the comb teeth of the gate electrode on the first conductivity type impurity diffusion regions of the drift region; and
implanting the first conductivity type impurity ions with the sidewall being used as a mask, to thereby form the first conductivity type source region and the first conductivity type drain region.

9. A method of manufacturing a semiconductor device according to claim 7, the semiconductor device including: a high withstanding voltage region in which the field effect transistor is formed; and a low withstanding voltage region in which a second field effect transistor having a withstanding voltage lower than a withstanding voltage of the field effect transistor is formed, wherein:
the forming the comb-shaped gate electrode further includes:
forming the comb-shaped gate electrode in the high withstanding voltage region; and
forming a second gate electrode in the low withstanding voltage region;
the forming the drift region further includes:
forming the drift region in the high withstanding voltage region in a state where the low withstanding voltage region is protected by a first resist film which selectively covers the low withstanding voltage region and is opened in the high withstanding voltage region; and
forming, in the low withstanding voltage region, a first conductivity type extension region on both sides of the second gate electrode formed in the low withstanding voltage region with the second gate electrode being used as a mask in a state where the high withstanding voltage region is protected by a second resist film which selectively covers the high withstanding voltage region and is opened in the low withstanding voltage region; and
the forming the first conductivity type drain region and the first conductivity type source region further includes implanting the first conductivity type impurity ions into both sides of the channel region of the substrate in the high withstanding voltage region, to thereby form the drain region and the source region, while simultaneously implanting the first conductivity type impurity ions into both sides of the second channel region of the substrate in the low withstanding voltage region, to thereby form a first conductivity type drain region and a first conductivity type source region.

10. A method of manufacturing a semiconductor device according to claim 9, wherein the forming the first conductivity type drain region and the first conductivity type source region further includes:
forming an insulating film on an entire surface over the substrate, and embedding the gate electrode and the second gate electrode in the insulating film;
etching back the insulating film by dry etching, to thereby form a sidewall on both sides of the gate electrode in a gate length direction in the high withstanding voltage region, the sidewall filling regions between the comb teeth of the gate electrode on the first conductivity type impurity diffusion regions in the drift region, and to thereby form a sidewall on both sides of the second gate electrode in the low withstanding voltage region; and
implanting the first conductivity type impurity ions in both of the high withstanding voltage region and the low withstanding voltage region with the respective sidewalls being used as a mask, to thereby form the first conductivity type drain region and the first conductivity type source region.
